(19) United States
(12) Patent Application Publication
(10) Pub. No.: US 2013/0200374 A1
(43) Pub. Date: Aug. 8, 2013

(54) Thin Film Transistor, Thin Film Transistor Substrate and Method for Manufacturing the Same

(71) Applicants: Yi-Fan Lee, Pingzhen City (TW); Hsiang-Hsien Chung, Taoyuan County (TW)

(72) Inventors: Yi-Fan Lee, Pingzhen City (TW); Hsiang-Hsien Chung, Taoyuan County (TW)

(73) Assignee: CHUNGHWA PICTURE TUBES, LTD., Bade City (TW)

(21) Appl. No.: 13/593,633

(22) Filed: Aug. 24, 2012

(30) Foreign Application Priority Data
Feb. 4, 2012 (TW) 101103686

(51) Int. Cl. H01L 29/786; H01L 21/336

(52) U.S. Cl. 257/57; 438/158; 257/66; 257/E29.273; 257/E21.409

(57) ABSTRACT

A thin film transistor is provided. The thin film transistor disposed on a substrate includes a gate electrode, a gate dielectric layer, a patterned semiconductor layer, a source electrode, a drain electrode covered with an anticorrosive conductive layer, a patterned passivation layer and a transparent conductive layer. The anticorrosive conductive layer includes indium tin oxide or indium zinc oxide, and is used to prevent the drain electrode from being over etched during the process of etching the passivation layer. A method for manufacturing the thin film transistor is also provided herein.

### RELATED APPLICATIONS

This application claims priority to Taiwan Application Serial Number 101103686, filed Feb. 4, 2012, which is herein incorporated by reference.

### BACKGROUND

1. Field of the Invention

The present invention relates to a thin film transistor and a method for manufacturing the thin film transistor.

2. Description of Related Art

A liquid crystal display device chiefly consists of a thin film transistor substrate, a color filter substrate and a liquid crystal molecule layer between the two substrates. Thin film transistors are disposed on the thin film transistor substrate, and each of the thin film transistors is mainly composed of a gate electrode, a gate dielectric layer, a source electrode, a drain electrode and a pixel electrode. A passivation layer is normally disposed over the source electrode and the drain electrode for protecting the thin film transistor under the passivation layer. The passivation layer may be patterned to expose a portion of the drain electrode. The pixel electrode may be disposed on the passivation layer and be electrically connected to the drain electrode.

During the process of patterning the passivation layer, an etchant is necessary for etching the passivation layer. However, in case of improper control of etching time, the drain electrode under the passivation layer may be damaged, thereby affecting the electrical connections between the drain electrode and other material layers. In more serious cases, it may cause the thin film transistor to fail.

Accordingly, an improved thin film transistor and a method for manufacturing the same are needed to solve the problems mentioned above.

### SUMMARY

An aspect of the present invention is to provide a thin film transistor that is capable of effectively improving the problems of a drain electrode thereof being improper etched in the prior art.

According to one embodiment of the present invention, the thin film transistor is disposed on a substrate which includes a gate electrode, a gate dielectric layer, a patterned semiconductor layer, a source electrode, a drain electrode, an anticorrosive conductive layer, a patterned passivation layer and a transparent conductive layer. The gate electrode is disposed on a substrate. The gate dielectric layer is covering the gate electrode. The patterned semiconductor layer is disposed on the gate dielectric layer. The source electrode and the drain electrode are disposed on the patterned semiconductor layer. The anticorrosive conductive layer is disposed on the upper surface of the drain electrode. The patterned passivation layer is covering the source electrode, the anticorrosive conductive layer and the patterned semiconductor layer, in which the patterned passivation layer has a contact window to expose a portion of the anticorrosive conductive layer over the drain electrode. The transparent conductive layer is disposed on the patterned passivation layer and is in contact with the portion of the anticorrosive conductive layer through the contact window.

According to one embodiment of the present invention, a thin film transistor substrate is provided which includes a substrate, a gate electrode, a gate pad, a first anticorrosive conductive layer, a gate dielectric layer, a patterned semiconductor layer, a source electrode, a drain electrode, a second anticorrosive conductive layer, a patterned passivation layer and a transparent conductive layer. The gate electrode and the gate pad are disposed on the substrate. The first anticorrosive conductive layer is disposed on an upper surface of the gate pad. The gate dielectric layer is covering the gate electrode and the first anticorrosive conductive layer, in which the gate dielectric layer has a first opening to expose a portion of the first anticorrosive conductive layer. The patterned semiconductor layer is disposed on the gate dielectric layer. The source electrode and the drain electrode are disposed on the patterned semiconductor layer. The second anticorrosive conductive layer is disposed on an upper surface of the drain electrode. The patterned passivation layer is covering the source electrode, the second anticorrosive conductive layer, the patterned semiconductor layer and the gate dielectric layer, in which the patterned passivation layer has a first contact window and a second opening, the first contact window exposing the portion of the second anticorrosive conductive layer, and the second opening is located on the first opening to expose the portion of the first anticorrosive conductive layer. The transparent conductive layer is disposed on the patterned passivation layer and is respectively in contact with the portion of the second anticorrosive conductive layer and the portion of the first anticorrosive conductive layer.

Another aspect of the present invention is to provide a method for manufacturing a thin film transistor. According to one embodiment of the present invention, the method includes the following steps. A gate electrode is formed on a substrate. A gate dielectric layer is formed covering the gate electrode. A patterned semiconductor layer is formed on the gate dielectric layer. A metal layer and an anticorrosive conductive material are sequentially deposited on the patterned semiconductor layer and the gate dielectric layer. The anticorrosive conductive material and the metal layer are patterned to form a source electrode, a drain electrode and an anticorrosive conductive layer, in which the anticorrosive conductive layer is located on the drain electrode. A patterned passivation layer is formed covering the source electrode, the anticorrosive conductive layer and the patterned semiconductor layer, in which the patterned passivation layer has a contact window to expose a portion of the anticorrosive conductive layer over the drain electrode. A transparent conductive layer is formed on the patterned passivation layer, in which the transparent conductive layer is in contact with the portion of the anticorrosive conductive layer.

According to one embodiment of the present invention, a method for manufacturing a thin film transistor substrate includes the following steps. A first metal layer and a first anticorrosive conductive material are sequentially deposited on a substrate. The first anticorrosive conductive material and the first metal layer are patterned to form a gate electrode, a gate pad and a first anticorrosive conductive layer, wherein the first anticorrosive conductive layer is located on the gate pad. A gate dielectric layer is formed covering the gate electrode and the first anticorrosive conductive layer. A patterned semiconductor layer is formed on the gate dielectric layer. A second metal layer and a second anticorrosive conductive material are sequentially deposited on the patterned semiconductor layer and the gate dielectric layer. The second anticorrosive conductive material and the second metal layer are patterned to form a source electrode, a drain electrode and a second anticorrosive conductive layer, in which the second anticorrosive conductive layer is located on the drain electrode. A passivation layer is formed covering the source electrode, the second anticorrosive conductive layer, the patterned semiconductor layer and the gate dielectric layer. A first contact window is formed through the passivation layer to expose a portion of the second anticorrosive conductive layer, and a second contact window is formed through the passivation layer and the gate dielectric layer to expose a portion of the first anticorrosive conductive layer. Next, a transparent conductive layer is formed on the passivation layer, in which the transparent conductive layer is respectively in contact with the portion of the second anticorrosive conductive layer through the first contact window and the portion of the first anticorrosive conductive layer through the second contact window.

As mentioned above, the anticorrosive conductive layer disposed on the upper surface of the drain electrode may be utilized to prevent the drain electrode from being improper etched during the process of etching the passivation layer.

### BRIEF DESCRIPTION OF THE DRAWINGS

The invention may be more fully understood by reading the following detailed description of the embodiment, with reference made to the accompanying drawings as follows:

FIG. 1 is a flow chart schematically illustrating a method for manufacturing a thin film transistor according to one embodiment of the present invention;

FIG. 2A to FIG. 2D are cross-sectional views schematically illustrating process steps for manufacturing a thin film transistor according to one embodiment of the present invention;

FIG. 3 is a flow chart schematically illustrating a method for manufacturing a thin film transistor substrate according to another embodiment of the present invention; and

FIG. 4A to FIG. 4F are cross-sectional views schematically illustrating process steps for manufacturing a thin film transistor substrate according to another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

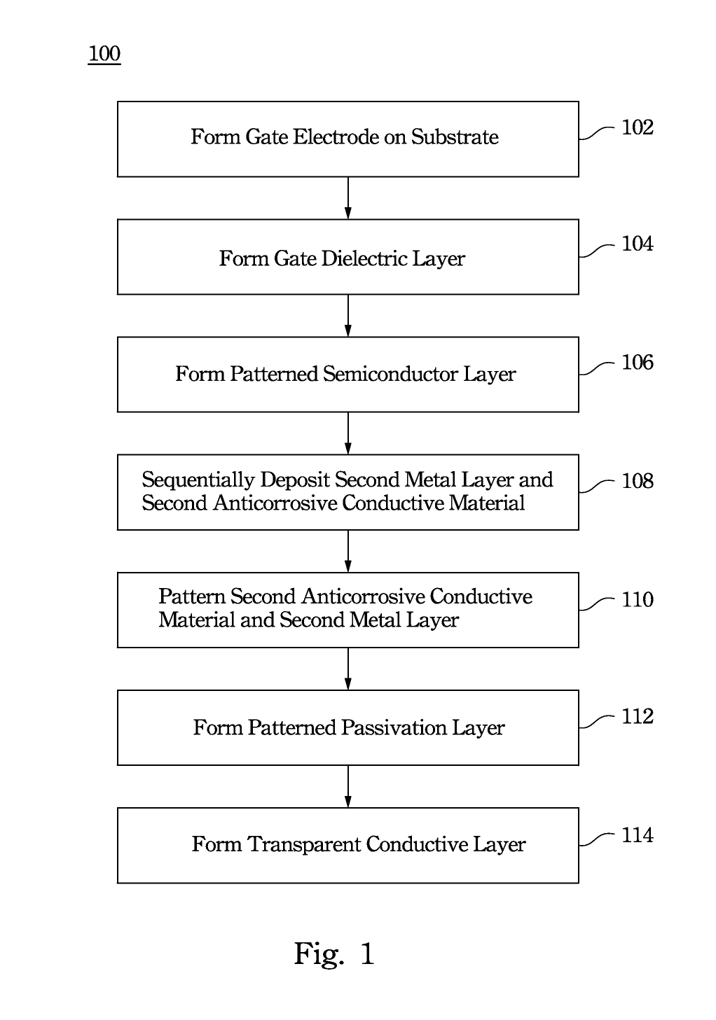

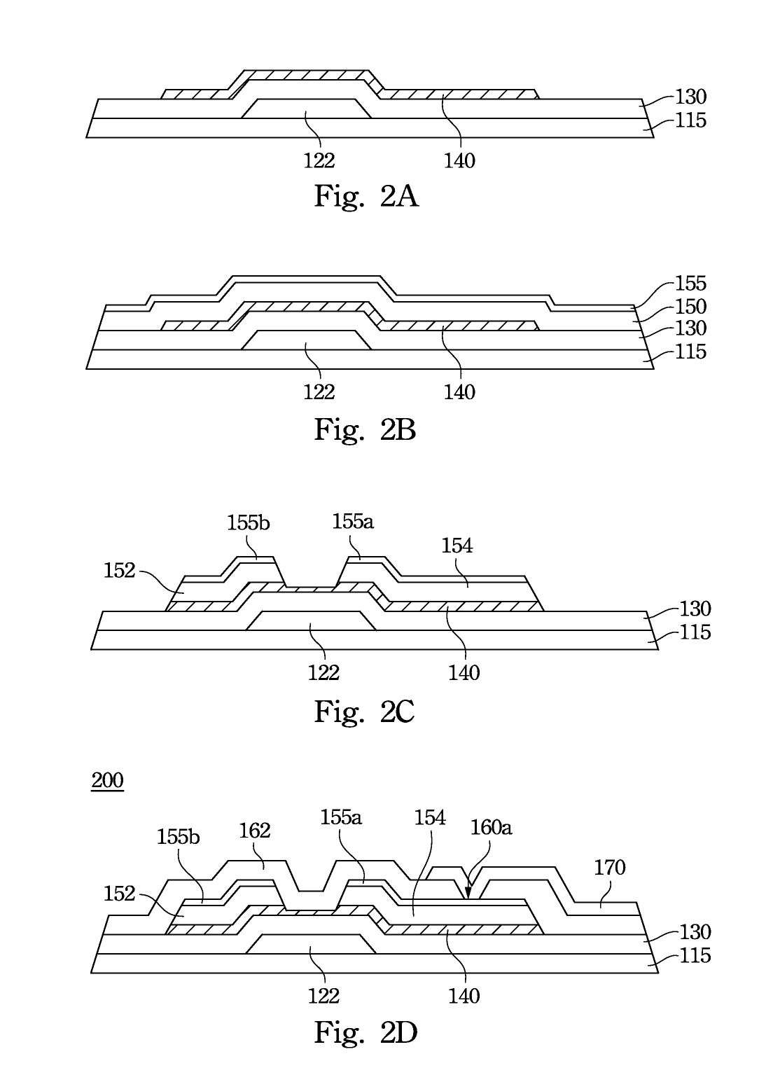

An aspect of the present invention is to provide a method for manufacturing a thin film transistor. FIG. 1 is a flow chart schematically illustrating a method 100 for manufacturing a thin film transistor according to one embodiment of the present invention. FIG. 2A to FIG. 2D are cross-sectional views schematically illustrating process steps of the method 100.

In step 102, a gate electrode 122 is formed on a substrate 115, as shown in FIG. 2A. The substrate 115 may be made of glass or quartz. The gate electrode 122 can be formed by any method known in the art. For instance, a metal layer is formed on the substrate 115 by a physical vapor deposition process, and then carrying out a photolithography process for thereby forming the gate electrode 122.

In step 104, a gate dielectric layer 130 is formed covering the gate electrode 122, as presented in FIG. 2A. The gate dielectric layer 130 may be made of silicon oxide or silicon nitride. For example, the gate dielectric layer 130 can be formed by means of a chemical vapor deposition process.

In step 106, a patterned semiconductor layer 140 is formed on the gate dielectric layer 130, as depicted in FIG. 2A. The patterned semiconductor layer 140 is arranged above the gate electrode 122 to form a channel layer of the thin film transistor in the follow-up processes. The patterned semiconductor layer 140 may be made using amorphous silicon, polysilicon or other semiconductor materials. In one example, a semiconductor layer may be blanket deposited through a chemical vapor deposition process, and then performing a photolithography process to form the patterned semiconductor layer 140.

In step 108, a second metal layer 150 and an second anticorrosive conductive material 155 are sequentially deposited on the patterned semiconductor layer 140 and the gate dielectric layer 130, as shown in FIG. 2B. In one embodiment, the second metal layer 150 includes molybdenum or molybdenum alloy, such as molybdenum-tantalum (MoTa) alloy, molybdenum-tungsten (MoW) alloy or molybdenum-aluminum (MoAl) alloy. The second anticorrosive conductive material 155 may include indium tin oxide (ITO) or indium zinc oxide (IZO). A physical vapor deposition process may be utilized to form the second metal layer 150 and the second anticorrosive conductive material 155.

In step 110, the second anticorrosive conductive material 155 and the second metal layer 150 are patterned to form a source electrode 152, a drain electrode 154 and a second anticorrosive conductive layer 155a, as depicted in FIG. 2C. In one embodiment, a patterned photoresist layer (not shown) may be formed on the second anticorrosive conductive material 155. Next, a portion without being covered by the patterned photoresist layer is removed by an etching process to thereby form the source electrode 152, the drain electrode 154 and the second anticorrosive conductive layer 155a. The second anticorrosive conductive layer 155a is located on the drain electrode 154 and has a substantially identical pattern in a top view as the drain electrode 154. In one example, the second anticorrosive conductive material 155 may be etched by an oxalic acid solution. The second metal layer 150 may be then etched by an aluminum acid solution, which may include phosphoric acid, nitric acid and acetic acid. In the embodiment in which the second metal layer 150 includes molybdenum or molybdenum alloy, the drain electrode 154 also includes the metal or the alloy. In the embodiment in which the second anticorrosive conductive material 155 includes ITO or IZO, the second anticorrosive conductive layer 155a includes ITO or IZO as well.

In one embodiment, a fourth anticorrosive conductive layer 155b can be simultaneously formed on the source electrode 152 while patterning the second anticorrosive conductive material 155 and the second metal layer 150. The fourth anticorrosive conductive layer 155b and the source electrode 152 have an identical pattern in a top view.

In step 112, a patterned passivation layer 162 is formed covering the source electrode 152, the second anticorrosive conductive layer 155a and the patterned semiconductor layer 140, as presented in FIG. 2D. The patterned passivation layer 162 has a first contact window 160a to expose a portion of the second anticorrosive conductive layer 155a. The patterned passivation layer 162 may be made of silicon oxide or silicon nitride. Specifically, a passivation layer may be blanket deposited by employing a chemical vapor deposition process, and then carrying out a photolithography process for thereby forming the first contact window 160a. During the etching process, sulfur hexafluoride (SF₆) is typically used as an etchant. Nonetheless, the etchant such as SF₆ is not only capable of etching the passivation layer but also capable of chemically reacting with the drain electrode 154 containing molybdenum. If SF₆ etches the drain electrode 154, it will severely affect the contact resistances between the drain electrode 154 and other layers for thereby causing the thin film transistor to fail. Accordingly, the second anticorrosive conductive layer 155a arranged on the drain electrode 154 is able to effectively prevent the drain electrode 154 from being etched during forming the contact window.

In step 114, a transparent conductive layer 170 is formed on the patterned passivation layer 162, as shown in FIG. 2D. The transparent conductive layer 170 may includes ITO, IZO or other transparent conductive metal oxides. The transparent conductive layer 170 is in contact with the exposed portion of the second anticorrosive conductive layer 155a. In other words, the transparent conductive layer 170 is electrically connected to the drain electrode 154 through the first contact window 160a. The contact resistance between the transparent conductive layer 170 and the drain electrode 154 may not be affected since the drain electrode 154 being etched will not occur. The transparent conductive layer 170 may be formed by means of any known process.

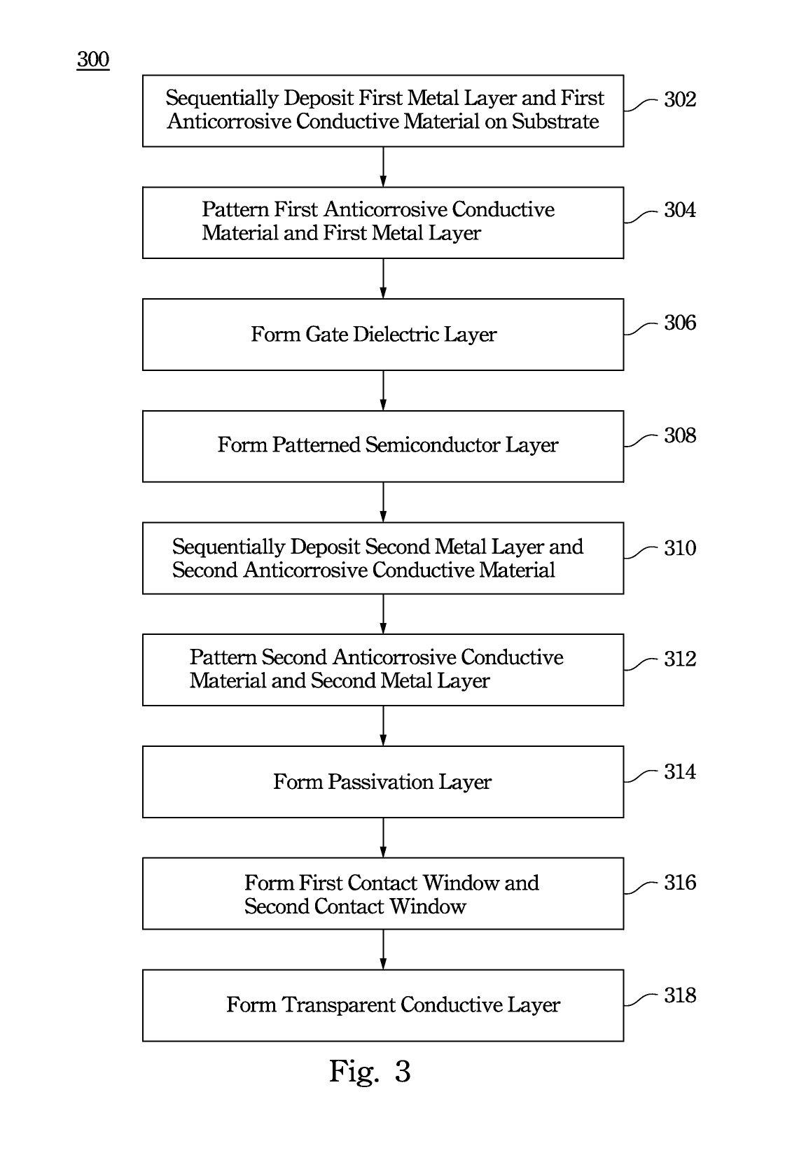

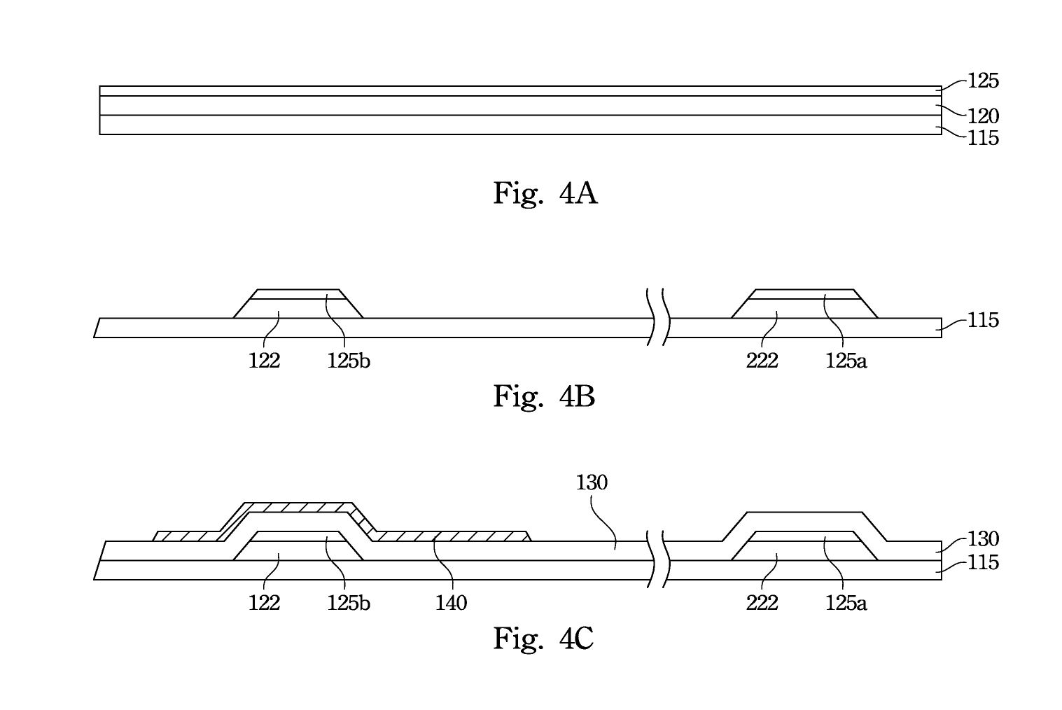

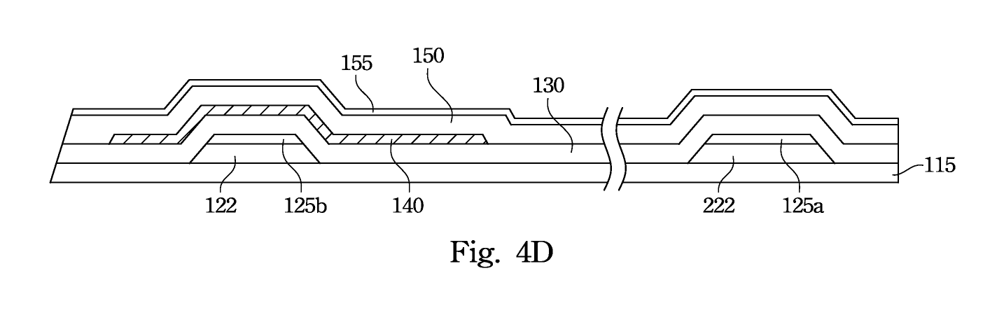

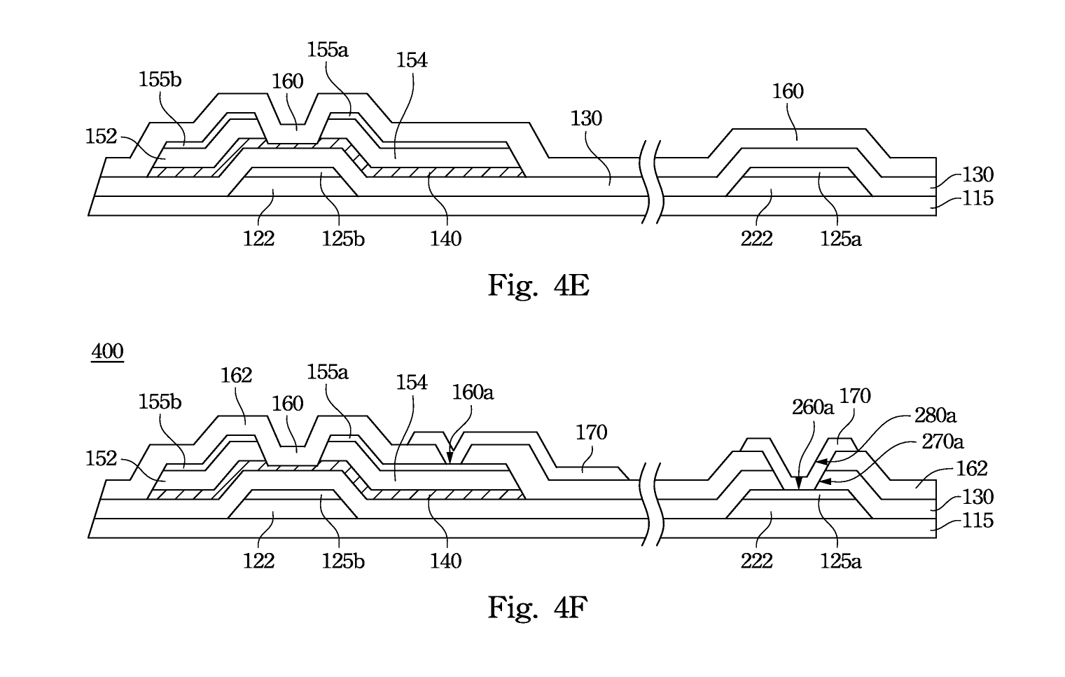

FIG. 3 is a flow chart schematically illustrating a method 300 for manufacturing a thin film transistor substrate according to another embodiment of the present invention. FIG. 4A to FIG. 4F are cross-sectional views schematically illustrating process steps of the method 300.

In step 302, a first metal layer 120 and a first anticorrosive conductive material 125 are sequentially deposited on a substrate 115, as depicted in FIG. 4A. In one embodiment, the first metal layer 120 includes molybdenum or molybdenum alloy, such as molybdenum-tantalum (MoTa) alloy, molybdenum-tungsten (MoW) alloy or molybdenum-aluminum (MoAl) alloy. The first anticorrosive conductive material 125 includes ITO or IZO. A physical vapor deposition process can be employed to respectively form the first metal layer 120 and the first anticorrosive conductive material 125.

In step 304, the first anticorrosive conductive material 125 and the first metal layer 120 are patterned to form a gate electrode 122, a gate pad 222 and a first anticorrosive conductive layer 125a, as shown in FIG. 4B. In one embodiment, a patterned photoresist layer (not shown) may be formed on the first anticorrosive conductive material 125. A portion without being covered by the patterned photoresist layer is then removed by an etching process for thereby forming the gate electrode 122, the gate pad 222 and the first anticorrosive conductive layer 125a. The first anticorrosive conductive layer 125a is located on the gate pad 222 and has a substantially identical pattern in a top view as the gate pad 222. In one example, the first anticorrosive conductive material 125 may be etched by the oxalic acid solution. Next, the first metal layer 120 may be etched by the aluminum acid solution, which may include phosphoric acid, nitric acid and acetic acid. In the embodiment in which the first metal layer 120 includes molybdenum or molybdenum alloy, the gate pad 222 includes the metal or the alloy as well.

In one embodiment, a third anticorrosive conductive layer 125b may be simultaneously formed on the gate electrode 122 while patterning the first anticorrosive conductive material 125 and the first metal layer 120, as presented in FIG. 4B.

In step 306, a gate dielectric layer 130 is formed covering the gate electrode 122, the gate pad 222, the first and the third anticorrosive conductive layers 125a, 125b, as shown in FIG. 4C. The materials of the gate dielectric layer 130 and the specific embodiments thereof may be the same as those described above in connection with step 104 of the method 100.

In step 308, a patterned semiconductor layer 140 is formed on the gate dielectric layer 130, as depicted in FIG. 4C. The specific embodiments of step 308 and the features thereof may be the same as those in connection with step 106 of the method 100.

In step 310, a second metal layer 150 and a second anticorrosive conductive material 155 are sequentially deposited on the patterned semiconductor layer 140 and the gate dielectric layer 130, as shown in FIG. 4D. The specific embodiments of step 310 and the features thereof may be the same as those with respect to step 108 of method 100.

In step 312, the second anticorrosive conductive material 155 and the second metal layer 150 are patterned to form a source electrode 152, a drain electrode 154 and a second anticorrosive conductive layer 155a, as depicted in FIG. 4E. The specific embodiments of step 312 and the features thereof may be the same as those in connection with step 110 of method 100.

In one embodiment, both the first and the second anticorrosive conductive materials 125, 155 for forming the first, the second, and the third anticorrosive conductive layers 125a, 155a, and 125b are made using the conductive material that is unable to chemically react with SF₆, such as ITO or IZO. The first and the second anticorrosive conductive layers 125a, 155a may be provided for preventing gate lines or data lines from damage. It is because during forming the metal layer, some foreign bodies may be situated in the metal layer. After carrying out a patterning process, broken gate lines or data lines may be typically formed due to the foreign bodies. However, in the manufacturing method of the embodiment of the present invention, the first and the second anticorrosive conductive materials 125, 155 are separately covering the first and the second metal layers 120, 150. Consequently, despite the presence of the foreign bodies in the first and the second metal layers 120, 150, the first and the second anticorrosive conductive materials 125, 155 are still capable of conducting electricity. In other words, the foreign bodies in the first and the second metal layers 120, 150 will not affect electrical properties of the circuits, thereby solving the problems mentioned above.

In step 314, a passivation layer 160 is formed covering the source electrode 152, the drain electrode 154, the gate pad 222, the second, the fourth and the third anticorrosive conductive layers 155a, 155b, 125b, the patterned semiconductor layer 140 and the gate dielectric layer 130, as depicted in FIG. 4E. For instance, the passivation layer 160 may be formed by means of utilizing a chemical vapor deposition process.

In step 316, a first contact window 160a is formed through the passivation layer 160, and a second contact window 260a is formed through the passivation layer 160 and the gate dielectric layer 130, as shown in FIG. 4F. The first contact window 160a and the second contact window 260a are respectively exposing a portion of the second anticorrosive conductive layer 155a and a portion of the first anticorrosive conductive layer 125a. Specifically, forming the second contact window 260a includes forming a second opening 280a through the passivation layer 160 and then forming a first opening 270a through the gate dielectric layer 130 under the second opening 280a. In other words, the second contact window 260a consists of the first opening 270a and the second opening 280a. When employing an etching process with SF₆ for forming the first and the second contact windows 160a, 260a, the first and the second anticorrosive conductive layers 125a, 155a may be respectively used to prevent the gate pad 222 and the drain electrode 154 from being etched by SF₆.

In step 318, a transparent conductive layer 170 is formed on the passivation layer 160, as presented in FIG. 4F. The transparent conductive layer 170 may be formed by any method in the art. The transparent conductive layer 170 is in contact with the exposed portion of the second anticorrosive conductive layers 155a and the exposed portion of the first anticorrosive conductive layers 125a. In other words, the transparent conductive layer 170 is electrically connected to the drain electrode 154 and the gate pad 222 respectively through the first and the second contact windows 160a, 260a. The contact resistance between the transparent conductive layer 170 and the drain electrode 154 may not be affected since the drain electrode 154 is unable to be etched.

Another aspect of the present invention is to provide a thin film transistor. In one embodiment, as shown in FIG. 2D, the thin film transistor 200 is disposed on a substrate 115 which includes a gate electrode 122, a gate dielectric layer 130, a patterned semiconductor layer 140, a source electrode 152, a drain electrode 154, a second anticorrosive conductive layer 155a, a patterned passivation layer 162 and a transparent conductive layer 170.

The gate electrode 122 is disposed on the substrate 115. The gate dielectric layer 130 is covering the gate electrode 122. The patterned semiconductor layer 140 is disposed on the gate dielectric layer 130. The source electrode 152 and the drain electrode 154 are disposed on the patterned semiconductor layer 140. The second anticorrosive conductive layer 155a is disposed on an upper surface of the drain electrode 154. The second anticorrosive conductive layer 155a includes ITO or IZO. The patterned passivation layer 162 is covering the source electrode 152, the second anticorrosive conductive layer 155a and the patterned semiconductor layer 140. The patterned passivation layer 162 has a first contact window 160a to expose a portion of the second anticorrosive conductive layer 155a. The transparent conductive layer 170 is disposed on the patterned passivation layer 162 and is in contact with the portion of the second anticorrosive conductive layer 155a through the first contact window 160a.

In one embodiment, as shown in FIG. 4F, a thin film transistor substrate 400 includes a substrate 115, a gate electrode 122, a gate pad 222, a first anticorrosive conductive layer 125a, a gate dielectric layer 130, a patterned semiconductor layer 140, a source electrode 152, a drain electrode 154, a second anticorrosive conductive layer 155a, a patterned passivation layer 162 and a transparent conductive layer 170.

The positions of the substrate 115, the gate electrode 122, the patterned semiconductor layer 140, the second anticorrosive conductive layer 155a, the source electrode 152, and the drain electrode 154 and other features thereof may be the same as those described above in connection with the thin film transistor 200. The gate pad 222 is disposed on the substrate 115. The first anticorrosive conductive layer 125a is disposed on an upper surface of the gate pad 222. The gate dielectric layer 130 is covering the gate electrode 122 and the first anticorrosive conductive layer 125a. The gate dielectric layer 130 has a first opening 270a to expose a portion of the first anticorrosive conductive layer 125a. The patterned passivation layer 162 has a first contact window 160a and a second opening 280a. The first contact window 160a is exposing a portion of the second anticorrosive conductive layer 155a. The second opening 280a is located on the first opening 270a to expose the portion of the first anticorrosive conductive layer 125a. The first and the second anticorrosive conductive layers 125a, 155a may include ITO or IZO. The transparent conductive layer 170 is disposed on the patterned passivation layer 162 and is respectively in contact with the portion of the second anticorrosive conductive layer 155a and the portion of the first anticorrosive conductive layer 125a.

As mentioned above, the anticorrosive conductive layer is disposed on the electrodes containing molybdenum which can solve the problems of electrodes being etched with SF₆ during the process of etching the passivation layer. Moreover, the anticorrosive conductive layer may be used to prevent circuits from interruption due to foreign bodies in the metal layer.

What is claimed is:

1. A thin film transistor, comprising:
a gate electrode disposed on a substrate;
a gate dielectric layer covering the gate electrode;
a patterned semiconductor layer disposed on the gate dielectric layer;
a source electrode and a drain electrode disposed on the patterned semiconductor layer;
an anticorrosive conductive layer disposed on an upper surface of the drain electrode;
a patterned passivation layer covering the source electrode, the anticorrosive conductive layer and the patterned semiconductor layer, wherein the patterned passivation layer has a contact window to expose a portion of the anticorrosive conductive layer; and
a transparent conductive layer disposed on the patterned passivation layer and in contact with the portion of the anticorrosive conductive layer through the contact window.

2. The thin film transistor of claim 1, wherein the anticorrosive conductive layer and the drain electrode have a substantially identical pattern, and the drain electrode includes molybdenum (Mo).

3. The thin film transistor of claim 1, wherein the anticorrosive conductive layer includes indium tin oxide (ITO) or indium zinc oxide (IZO).

4. A thin film transistor substrate, comprising:
a substrate;
a gate electrode and a gate pad disposed on the substrate;
a first anticorrosive conductive layer disposed on an upper surface of the gate pad;
a gate dielectric layer covering the gate electrode and the first anticorrosive conductive layer, wherein the gate dielectric layer has a first opening to expose a portion of the first anticorrosive conductive layer;
a patterned semiconductor layer disposed on the gate dielectric layer;
a source electrode and a drain electrode disposed on the patterned semiconductor layer;
a second anticorrosive conductive layer disposed on an upper surface of the drain electrode;
a patterned passivation layer covering the source electrode, the second anticorrosive conductive layer, the patterned semiconductor layer and the gate dielectric layer, wherein the patterned passivation layer has a first contact window and a second opening, the first contact window exposing a portion of the second anticorrosive conductive layer, and the second opening is located on the first opening to expose the portion of the first anticorrosive conductive layer; and
a transparent conductive layer disposed on the patterned passivation layer and respectively in contact with the portion of the second anticorrosive conductive layer and the portion of the first anticorrosive conductive layer.

5. The substrate of claim 4, wherein the first anticorrosive conductive layer and the gate pad have an identical pattern, the second anticorrosive conductive layer and the drain electrode having an identical pattern, and the gate pad and the drain electrode include molybdenum.

6. The substrate of claim 4, wherein the first anticorrosive conductive layer and the second anticorrosive conductive layer include indium tin oxide or indium zinc oxide.

7. A method for manufacturing a thin film transistor, comprising following steps:
forming a gate electrode on a substrate;
forming a gate dielectric layer covering the gate electrode;
forming a patterned semiconductor layer on the gate dielectric layer;
sequentially depositing a metal layer and an anticorrosive conductive material on the patterned semiconductor layer and the gate dielectric layer;
patterning the anticorrosive conductive material and the metal layer to form a source electrode, a drain electrode and an anticorrosive conductive layer, wherein the anticorrosive conductive layer is located on the drain electrode;
forming a patterned passivation layer covering the source electrode, the anticorrosive conductive layer and the patterned semiconductor layer, wherein the patterned passivation layer has a contact window to expose a portion of the anticorrosive conductive layer over the drain electrode; and
forming a transparent conductive layer on the patterned passivation layer, wherein the transparent conductive layer is in contact with the portion of the anticorrosive conductive layer.

8. The method of claim 7, wherein the drain electrode includes molybdenum.

9. The method of claim 7, wherein the anticorrosive conductive layer includes indium tin oxide (ITO) or indium zinc oxide (IZO).

10. The method of claim 7, wherein the step of patterning the anticorrosive conductive material and the metal layer comprises etching the anticorrosive conductive material with an oxalic acid solution.

11. A method for manufacturing a thin film transistor substrate, comprising following steps:
sequentially depositing a first metal layer and a first anticorrosive conductive material on a substrate;
patterning the first anticorrosive conductive material and the first metal layer to form a gate electrode, a gate pad and a first anticorrosive conductive layer, wherein the first anticorrosive conductive layer is located on the gate pad;
forming a gate dielectric layer covering the gate electrode and the first anticorrosive conductive layer;
forming a patterned semiconductor layer on the gate dielectric layer;
sequentially depositing a second metal layer and a second anticorrosive conductive material on the patterned semiconductor layer and the gate dielectric layer;
patterning the second anticorrosive conductive material and the second metal layer to form a source electrode, a drain electrode and a second anticorrosive conductive layer, wherein the second anticorrosive conductive layer is located on the drain electrode;
forming a passivation layer covering the source electrode, the second anticorrosive conductive layer, the patterned semiconductor layer and the gate dielectric layer;
forming a first contact window through the passivation layer to expose a portion of the second anticorrosive conductive layer, and forming a second contact window through the passivation layer and the gate dielectric layer to expose a portion of the first anticorrosive conductive layer; and
forming a transparent conductive layer on the passivation layer, wherein the transparent conductive layer is in contact with the portion of the second anticorrosive conductive layer respectively through the first contact window and the portion of the first anticorrosive conductive layer through the second contact window.

12. The method of claim 11, wherein the gate pad and the drain electrode include molybdenum.

13. The method of claim 11, wherein the first anticorrosive conductive layer and the second anticorrosive conductive layer include indium tin oxide (ITO) or indium zinc oxide (IZO).

14. The method of claim 11, wherein the step of patterning the first anticorrosive conductive material and the first metal layer comprises etching the first anticorrosive conductive material with an oxalic acid solution.
